(19) United States
(12) Patent Application Publication
(10) Pub. No.: US 2010/0026869 A1
(43) Pub. Date: Feb. 4, 2010

(54) IMAGE SENSOR AND METHOD FOR MANUFACTURING THE SAME

(76) Inventor: Chang Hun Han, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/508,152

(22) Filed: Jul. 23, 2009

(30) Foreign Application Priority Data
Jul. 29, 2008 (KR) 10-2008-0074182

(51) Int. Cl. H01L 31/18; H04N 5/335

(52) U.S. Cl. 348/311; 438/75; 348/E05.091; 257/E21.158

(57) ABSTRACT

An image sensor and a method for manufacturing the same are provided. The image sensor comprises a readout circuitry, an interlayer dielectric, an interconnection, and a CuInGaSe2 (CIGS) image sensing device. The readout circuitry is disposed on a first substrate. The interlayer dielectric is disposed over the first substrate. The interconnection is in the interlayer dielectric and electrically connected to the readout circuitry. The CIGS image sensing device is disposed over the interconnection and electrically connected to the readout circuitry through the interconnection.

### CROSS-REFERENCE TO RELATED APPLICATION

This application claims the benefit under 35 U.S.C. §119 of Korean Patent Application No. 10-2008-0074182, filed Jul. 29, 2008, which is hereby incorporated by reference in its entirety.

### BACKGROUND

The present disclosure relates to an image sensor and a method for manufacturing the same.

An image sensor is a semiconductor device for converting an optical image into an electric signal. The image sensor may be roughly classified into a charge coupled device (CCD) image sensor and a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called Airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a three-dimensional (3D) image sensor). The photodiode is connected with the readout circuitry through a metal interconnection.

In a related-art, since the energy band gap of the Si layer where a photodiode is formed is about 1.1 eV, there is a limitation in that it is effectively not possible to absorb light other than a visible ray. Accordingly, the related-art can not appropriately function on surveillance cameras for night vision or automobile cameras necessary for night driving.

In addition, since both the source and the drain at sides of the transfer transistor are typically heavily doped with N-type impurities, a charge sharing phenomenon occurs. When the charge sharing phenomenon occurs, the sensitivity of an output image is reduced and an image error may be generated. Also, because a photo charge does not readily move between the photodiode and the readout circuitry, a dark current is generated and/or saturation and sensitivity are reduced.

### BRIEF SUMMARY

Embodiments provide an image sensor capable of performing in surveillance cameras for night vision or car cameras necessary for night driving, and a method for manufacturing the same.

Embodiments also provide an image sensor where a charge sharing does not occur while increasing a fill factor and a method for manufacturing the same.

Embodiments also provide an image sensor that can minimize a dark current source and inhibit saturation reduction and sensitivity degradation by forming a smooth transfer path of a photo charge between a photodiode and a readout circuit, and a method for manufacturing the same.

In one embodiment, an image sensor comprises: a readout circuitry on a first substrate; an interlayer dielectric over the first substrate; an interconnection electrically connected to the readout circuitry in the interlayer dielectric; and a CuInGaSe2 (CIGS) image sensing device over the interconnection.

In another embodiment, a method for manufacturing an image sensor comprises: forming a readout circuitry on a first substrate; forming an interlayer dielectric over the first substrate; forming an interconnection electrically connected to the readout circuitry in the interlayer dielectric; and forming a CIGS image sensing device over the interconnection.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2 to 8 are views illustrating a method for manufacturing an image sensor according to a first embodiment.

FIG. 9 is a cross-sectional view of an image sensor according to a second embodiment.

### DETAILED DESCRIPTION

Hereinafter, an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

FIG. 1 is a cross-section view of an image sensor according to an embodiment.

Referring to FIG. 1, an image sensor can include a readout circuitry 120 on a first substrate 100; an interlayer dielectric 160 on the first substrate 100; an interconnection 150 in the interlayer dielectric 160 and electrically connected to the readout circuitry 120; and a CIGS (CuInGaSe2: copper indium gallium diselenide) image sensing device 210 on the interconnection 180 and electrically connected to the readout circuitry 120 through the interconnection 150.

The image sensing device 210 may be a photodiode. However, embodiments are not limited thereto. For example, the image sensing device 210 may be a photogate, or a combination of the photodiode and the photogate. Embodiments include a photodiode formed in a crystalline semiconductor layer as an example, but without being limited thereto, include a photodiode formed in amorphous semiconductor layer.

Embodiments provide a high sensitivity and broadband image sensor using polycrystal CIGS instead of Silicon, thereby capable exerting excellent performance on surveillance cameras for night vision or car cameras necessary for night driving.

According to an embodiment, the device is designed to provide a potential difference between the source and drain of the transfer transistor (Tx), thereby enabling the full dumping of a photo charge. Accordingly, a photo charge generated in the photodiode is dumped to the floating diffusion region, thereby increasing the output image sensitivity.

According to an embodiment, a first conductive connection (not shown in FIG. 1) is formed between the photodiode and the readout circuit to create a smooth transfer path of a photo charge, thereby making it possible to minimize a dark current source and inhibit saturation reduction and sensitivity degradation.

Unexplained reference numerals in FIG. 1 will be described with reference to the drawings illustrating a method for manufacturing the image sensor below.

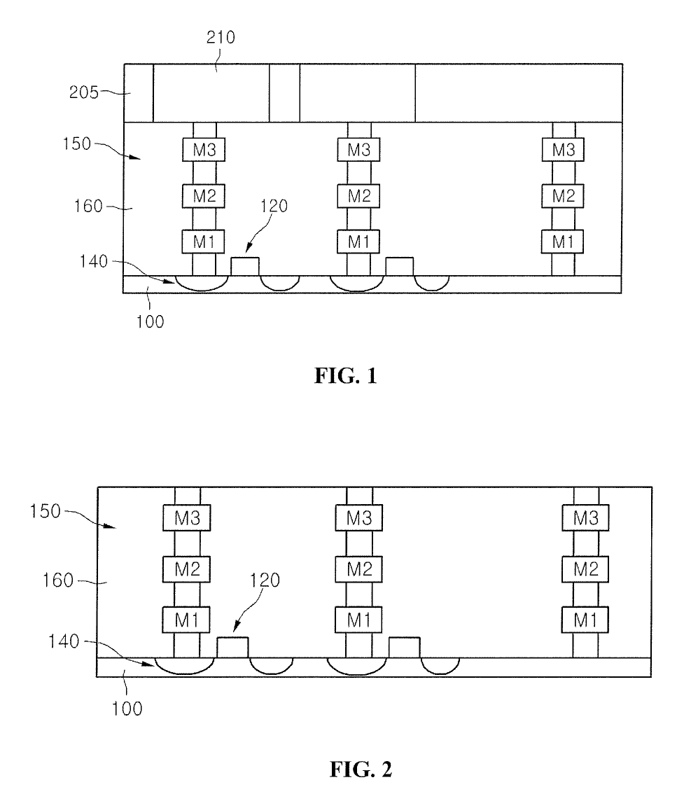

Hereinafter, a method for manufacturing an image sensor according to a first embodiment will be described with reference to FIGS. 2 to 8.

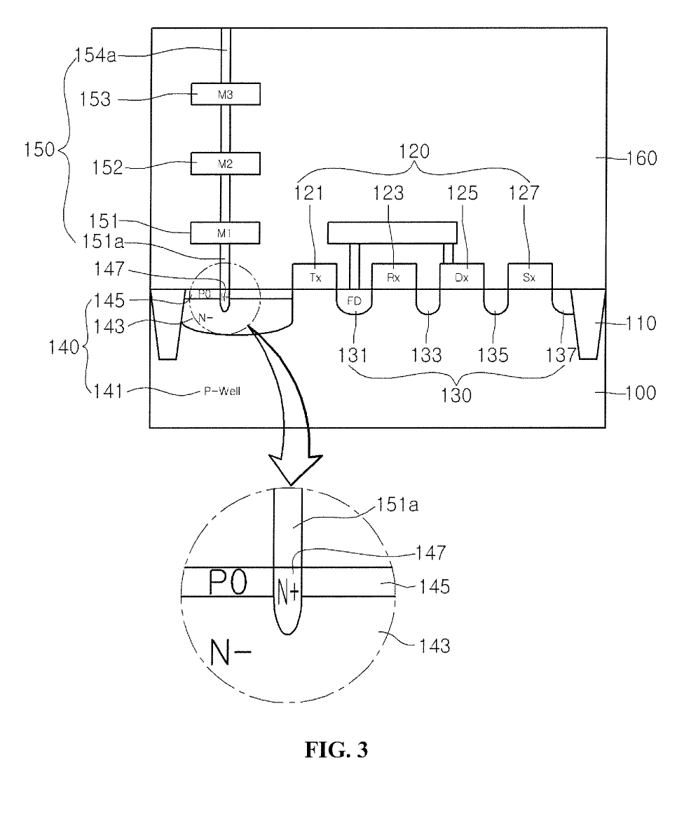

As illustrated in FIG. 2, a first substrate 100 including an interconnection 150 and a readout circuitry 120 is prepared. FIG. 3 is a detail view of FIG. 2 in accordance with the first embodiment. Hereinafter, descriptions will be made on the basis of FIG. 3.

An active region is defined by forming a device separation layer 110 in the first substrate 100. The readout circuitry 120 is formed on the active region and may include a transfer transistor (Tx) 121, a reset transistor (Rx) 123, a drive transistor (Dx) 125, and a select transistor (Sx) 127. A floating diffusion region (FD) 131 and an ion implantation region 130 including a source/drain region 133, 135 and 137 for each transistor may be formed. In an embodiment, a noise removal circuit (not shown) may be added to improve sensitivity.

The forming of the readout circuitry 120 on the first substrate 100 may include forming an electrical junction region 140 on the first substrate 100 and forming a first conductive connection 147 connected to the interconnection 150 at an upper part of the electrical junction region 140.

For example, the electrical junction region 140 may be a P-N junction 140, but is not limited thereto. For example, the electrical junction region 140 may include a first conductive-type ion implantation region 143 formed on a second conductive-type well 141 or a second conductive-type epitaxial layer, and a second conductive-type ion implantation layer 145 formed on the first conductive-type ion implantation region 143. For example, referring to FIGS. 2 and 3, the P-N junction 140 may be a P0(145)/N−(143)/P−(141) junction, but embodiments are not limited thereto. In addition, the first substrate 100 may be a second conductive type, but embodiments are not limited thereto.

According to an embodiment, the device is designed to provide a potential difference between the source and drain of the transfer transistor (Tx), thereby enabling the full dumping of a photo charge. Accordingly, a photo charge generated in the photodiode is dumped to the floating diffusion region, thereby increasing the output image sensitivity.

That is, referring to FIG. 3, the electrical junction region 140 is formed in the first substrate 100 including the readout circuit 120 to provide a potential difference between the source and drain of the transfer transistor (Tx) 121, thereby implementing the full dumping of a photo charge.

Hereinafter, a dumping structure of a photo charge according to an embodiment will be described in detail.

In an embodiment, unlike a floating diffusion (FD) 131 node having an N+ junction, the P/N/P junction 140 of the electrical junction region 140 is pinched off at a predetermined voltage without an applied voltage being fully transferred thereto. This voltage is called a pinning voltage. The pinning voltage depends on the P0 (145) and N− (143) doping concentration.

Specifically, electrons generated in the photodiode 210 are transferred to the PNP junction 140, and they are transferred to the floating diffusion (FD) 131 node to be converted into a voltage when the transfer transistor (Tx) 121 is turned on.

The maximum voltage of the P0/N−/P− junction 140 becomes the pinning voltage, and the maximum voltage of the FD 131 node becomes V_{dd}−Vₜₕ_{_{—}}_{Rx}. Therefore, due to a potential difference between the source and drain of the Tx 131, without charge sharing, electrons generated in the photodiode 210 on the chip can be completely dumped to the FD 131 node.

That is, according to this embodiment, not an N+/P-well junction but a P0/N−/P-well junction is formed in a silicon substrate (Si-Sub) of the first substrate 100. The reason for this is that, in a four transistor active pixel sensor (4-Tr APS) reset operation, a positive (+) voltage is applied to the N− region (143) in the P0/N−/P-well junction and a ground voltage is applied to the P0 region (145) and the P-well (141) and thus a P0/N−/P-well double junction generates a pinch-off at a predetermined voltage or higher like in a BJT structure. This is called a pinning voltage. Thus, a potential difference occurs between the source and drain of the Tx 121, thus making it possible to inhibit a charge sharing phenomenon due to full dumping of photocharges from the N− region at the source to FD through Tx in a Tx on/off operation.

Thus, unlike the related art case of connecting a photodiode simply to an N+ junction, this embodiment makes it possible to inhibit saturation reduction and sensitivity degradation.

Thereafter, a first conductive connection 147 is formed between the photodiode and the readout circuit to create a smooth transfer path of a photo charge, thereby making it possible to minimize a dark current source and inhibit saturation reduction and sensitivity degradation.

To this end, the first embodiment may form an N+ doping region as a first conductive connection 147 for an ohmic contact on the surface of the P0/N−/P− junction 140. The N+ region (147) may be formed such that it pierces the P0 region (145) to contact the N− region (143).

On the other hand, the width of the first conductive connection 147 may be minimized to inhibit the first conductive connection 147 from being a leakage source. To this end, a plug implant can be performed after etching a contact hole for a first metal contact 151a, but embodiments are not limited thereto. As another example, an ion implantation pattern (not shown) may be formed, and the ion implantation pattern may be used as an ion implantation mask to form the first conductive connection 147.

That is, a reason why an N+ doping is locally performed only on a contact formation region as described in the first embodiment is to minimize a dark signal and implement the smooth formation of an ohmic contact. If the entire width of the Tx source region is N+ doped like the related art, a dark signal may increase due to an Si surface dangling bond.

Next, an interlayer dielectric 160 may be formed on the first substrate 100, and an interconnection 150 may be formed. The interconnection 150 may include the first metal contact 151a, a first metal 151, a second metal 152, a third metal 153, and a fourth metal contact 154a, but embodiments are not limited thereto.

Next, referring to FIG. 4, an insulating layer 205 is formed over the interconnection 150. For example, the insulating layer 205 may be formed of an oxide or a nitride.

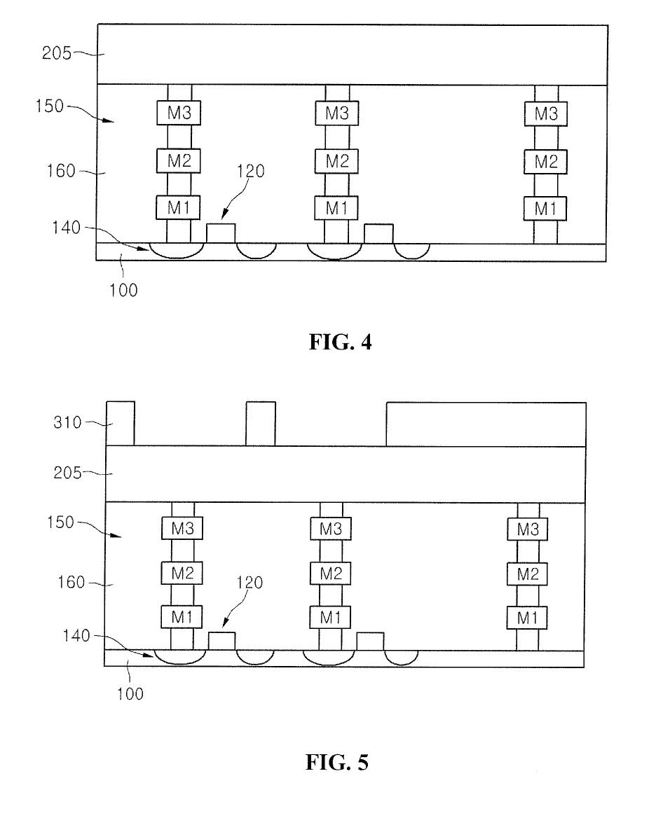

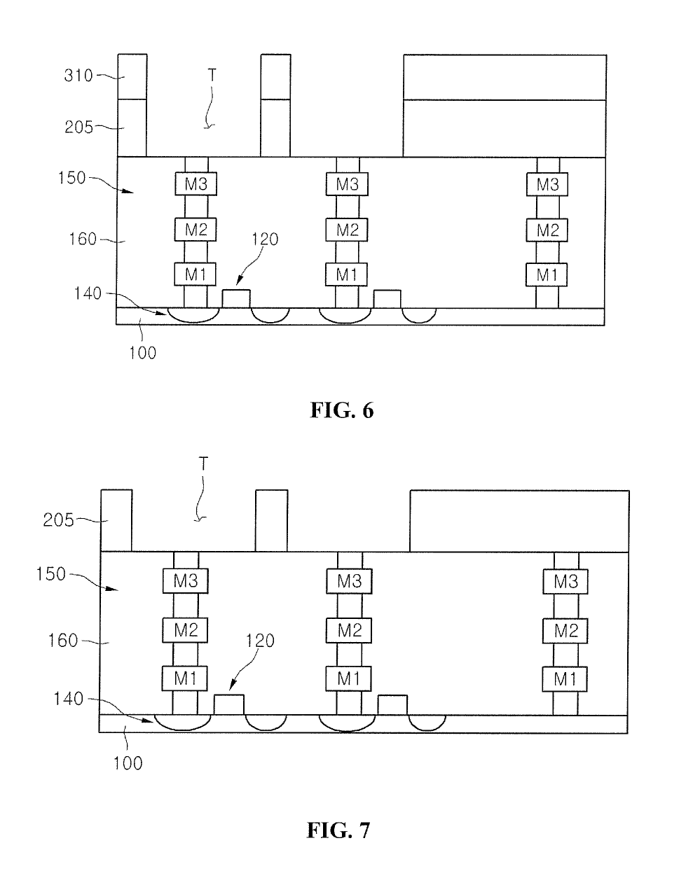

Thereafter, as shown in FIG. 5, a photoresist pattern 310 is formed to expose a region where the image sensing device is to be formed. Then, referring to FIG. 6, portions of the insulating layer 205 are removed using the photoresist pattern 310 as an etching mask, forming a trench T exposing the upper side of the interconnection 150.

In this case, the remaining insulating layer 205 may serve as an isolating layer between pixels. In another embodiment, an image sensing device layer may be formed and portions of the image sensing device layer can be removed from regions between the pixels. Thereafter, an insulating layer may be formed in the exposed regions between the pixels after the image sensing device layer is removed from the regions between the pixels.

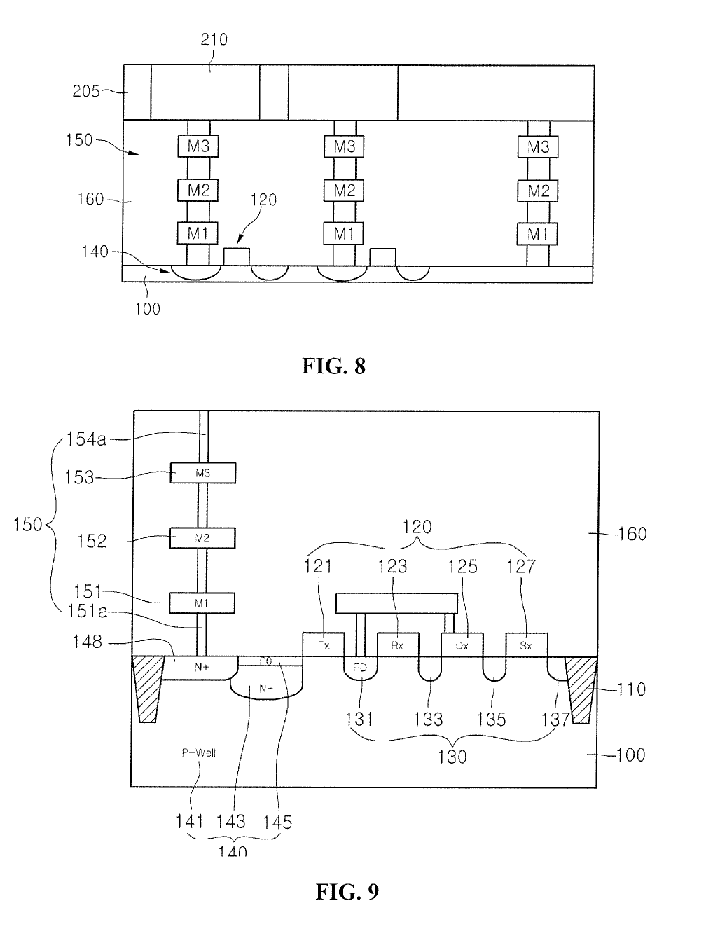

Referring to FIGS. 7 and 8, after the photoresist pattern 310 is removed, a CIGS (CuInGaSe2) image sensing device 210 is filled in the trench T.

For example, the CIGS image sensing device 210 may be formed through a co-evaporation method, an electro-deposition method, a sputtering method, or a molecular organic CVD (MOCVD) method.

As one example, in the co-evaporation method, a CIGS image sensing device may be formed in a trench through a vacuum evaporation by performing resistance-heating on elements (for example, Cu, In, Ga, and Se) in an electric furnace installed in a vacuum chamber.

As another example, in the sputtering method, after a Cu—Ga/In alloy thin film is formed by sequentially sputtering an alloy target of Cu and Ga and an In target, a CIGS thin film may be formed by performing heat treatment on the Cu—Ga/In alloy thin film under a hydrogen selenide (H2Se) atmosphere.

An image sensor including the CIGS image sensing device according to an embodiment is able to recognize an image at a dark place of about 0.0001 lux. Accordingly, the image sensor can be applied to automobile parts or security industries.

Also, the CIGS image sensing device according to an embodiment can provide a high-sensitivity and broadband image sensor because having an optical absorption coefficient of about one hundred times compared to a silicon image sensing device. In addition, the CIGS image sensing device according to an embodiment can not only obtain photoelectric conversion efficiency of approximately two or more times greater than the silicon image sensing device, but also can be formed over a readout circuitry. Accordingly, the CIGS image sensing device allows a fill factor to approach about 100%. According to an embodiment, the CIGS image sensing device can senses a broadband image at wavelengths from about 400 nm to about 1,300 nm.

Furthermore, the CIGS image sensing device according to an embodiment can change a wavelength band by changing the composition ratio of In and Ga.

Thereafter, processes for an upper electrode (not shown) and a color filter (not shown) may be performed.

FIG. 9 is a cross-sectional view of an image sensor according to a second embodiment, and shows a detail view of a first substrate including an interconnection 150 formed therein.

The image sensor according to the second embodiment may include a readout circuitry 120 on a first substrate 100; an interlayer dielectric 160 on the first substrate 100; an interconnection 150 in the interlayer dielectric 160 and electrically connected to the readout circuitry 120; and a CIGS image sensing device 210 on the interconnection 150 and electrically connected to the readout circuitry 120 through the interconnection 150.

The second embodiment may adopt the technical features of the first embodiment.

The second embodiment provides a high sensitivity and broadband image sensor using polycrystal CIGS instead of Si, thereby exerting excellent performance for surveillance cameras for night vision or car cameras necessary for night driving.

According to the second embodiment, the device is designed to provide a potential difference between the source and drain of the transfer transistor (Tx), thereby enabling the full dumping of a photo charge.

According to the second embodiment, a charge connection region is formed between a photodiode and a readout circuit to create a smooth transfer path of a photo charge, thereby making it possible to minimize a dark current source and inhibit saturation reduction and sensitivity degradation.

Unlike the first embodiment, the first conductive connection 148 is formed at one side of the electrical junction region 140.

An N+ connection region 148 may be formed at a P0/N−/P− junction 140 for an ohmic contact. In this case, a leakage source may be generated during the formation process of an N+ connection region 148 and a M1C contact 151a. This is because an electric field (EF) may be generated over the Si surface due to operation while a reverse bias is applied to the P0/N−/P− junction 140. A crystal defect generated during the contact formation process inside the electric field may become a leakage source.

Also, when the N+ connection region 148 is formed over the surface of the P0/N−/P− junction 140, an electric field may be additionally generated due to the N+/P0 junction 148/145. This electric field may also become a leakage source.

Therefore, the second embodiment proposes a layout in which the first contact plug 151a is formed in an active region not doped with a P0 layer, but including N+ connection region 148 that is connected to the N− region 143.

According to the second embodiment, the electric field is not generated on and/or over the Si surface, which can contribute to reduction in a dark current of a 3D integrated CIS.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry on a first substrate;
an interlayer dielectric over the first substrate;
an interconnection in the interlayer dielectric and electrically connected to the readout circuitry; and
a CuInGaSe2 (CIGS) image sensing device over the interconnection and electrically connected to the readout circuitry through the interconnection.

2. The image sensor according to claim 1, wherein the CIGS image sensing device senses a broadband image at wavelengths from about 400 nm to about 1,300 nm.

3. The image sensor according to claim 1, further comprising an electrical junction region in the first substrate and electrically connecting the interconnection to the readout circuitry.

4. The image sensor according to claim 3, wherein the electrical junction region comprises:
a first conductive type ion implantation region in the first substrate; and
a second conductive type ion implantation region over the first conductive type ion implantation region.

5. The image sensor according to claim 3, wherein the readout circuitry has a potential difference between the source and the drain of a transistor, the electrical junction region being at the source of the transistor.

6. The image sensor according to claim 3, wherein the electrical junction region is a PN junction.

7. The image sensor according to claim 3, further comprising a first conductive connection between the electrical junction region and the interconnection.

8. The image sensor according to claim 7, wherein the first conductive connection is electrically connected to the interconnection at an upper part of the electrical junction region.

9. The image sensor according to claim 7, wherein the first conductive connection is at one side of the electrical junction region and electrically connects the interconnection to the electrical junction region.

10. The image sensor according to claim 3, wherein the electrical junction region is a PNP junction.

11. A method for manufacturing an image sensor, comprising:
forming a readout circuitry on a first substrate;
forming an interlayer dielectric over the first substrate;
forming an interconnection in the interlayer dielectric and electrically connected to the readout circuitry; and
forming a CIGS image sensing device over the interconnection, the CIGS image sensing device being electrically connected to the readout circuitry through the interconnection.

12. The method according to claim 11, wherein the CIGS image sensing device is formed through a co-evaporation method or a sputtering method.

13. The method according to claim 11, wherein the CIGS image sensing device is formed through vapor deposition.

14. The method according to claim 11, further comprising forming an electrical junction region in the first substrate and electrically connecting the interconnection to the readout circuitry.

15. The method according to claim 14, wherein the forming of the electrical junction region comprises:
forming a first conductive type ion implantation region in the first substrate; and
forming a second conductive type ion implantation region on the first conductive type ion implantation region.

16. The method according to claim 14, wherein the readout circuitry has a potential difference between the source and the drain of a transistor, the electrical junction region being at the source of the transistor.

17. The method according to claim 14, wherein the electrical junction region is a PN junction.

18. The method according to claim 14, further comprising forming a first conductive connection between the electrical junction region and the interconnection.

19. The method according to claim 18, wherein the first conductive connection is electrically connected to the interconnection at an upper part of the electrical junction region.

20. The method according to claim 18, wherein the first conductive connection is formed at one side of the electrical junction region and electrically connects the interconnection to the electrical junction region.
